(19) United States
(12) Patent Application Publication
(10) Pub. No.: US 2014/0028326 A1
(43) Pub. Date: Jan. 30, 2014

(54) DA-CONVERTER AND TEST APPARATUS

(71) Applicant: ADVANTEST CORPORATION, Tokyo (JP)

(72) Inventors: Masayuki KAWABATA, Saitama (JP); Yasuhide KURAMOCHI, Gunma (JP)

(21) Appl. No.: 13/891,193

(22) Filed: May 10, 2013

(30) Foreign Application Priority Data
Jul. 27, 2012 (JP) 2012-166617

(51) Int. Cl. H03M 1/00; G01R 1/30

(52) U.S. Cl. CPC H03M 1/002; G01R 1/30
USPC 324/555; 341/145

(57) ABSTRACT

A DA conversion apparatus comprising a DA converting section that includes a plurality of analog elements; and a control section that generates first shift data and second shift data by shifting the input digital data by respective shift amounts of M bits and N bits, and controls the analog elements based on the first shift data and the second shift data, wherein the control section changes a control state for each of the common analog elements according to the bit shift amounts M and N in the control section, between at least two control states including a control state in which the common analog element is controlled according to higher-order bits of the first shift data and a control state in which the common analog element is controlled according higher-order bits of the second shift data.

### BACKGROUND

1. Technical Field

The present invention relates to a DA conversion apparatus and a test apparatus.

2. Related Art

Conventionally, multiplying a digital input signal by a coefficient is a known technique for changing the amplitude of the output of a DA converter. Documents relating to the prior art are listed below. Patent Document 1: Japanese Patent Application Publication No. 2007-235210 Patent Document 2: Japanese Patent Application Publication No. 2000-138585 Patent Document 3: Japanese Patent Application Publication No. 2008-153928 Patent Document 4: Japanese Patent Application Publication No. 2000-165700

However, conventional techniques for changing the amplitude require a complicated calculation or a complicated circuit. Furthermore, the power consumed by a variable amplitude DA converter is preferably as low as possible.

### SUMMARY

Therefore, it is an object of an aspect of the innovations herein to provide DA conversion apparatus and a test apparatus, which are capable of overcoming the above drawbacks accompanying the related art. The above and other objects can be achieved by combinations described in the claims. According to a first aspect of the present invention, provided is a DA conversion apparatus that converts input digital data into an output analog signal, comprising a DA converting section that includes a plurality of analog elements and generates the output analog signal by combining each of a plurality of analog levels output by the analog elements; and a control section that generates first shift data and second shift data by shifting the input digital data by respective shift amounts of M bits and N bits, and controls the analog elements based on the first shift data and the second shift data. Two or more of the analog elements are common analog elements that are provided in common for the first shift data and second shift data, and the control section changes a control state for each of the common analog elements according to the bit shift amounts M and N in the control section, between at least two control states including a control state in which the common analog element is controlled according to higher-order bits of the first shift data and a control state in which the common analog element is controlled according higher-order bits of the second shift data.

According to a second aspect of the present invention, provided is a test apparatus that tests a device under test, comprising the DA conversion apparatus according to the first aspect; and a voltage supplying section that applies to the device under test a test voltage corresponding to an output analog signal output by the DA conversion apparatus.

The summary clause does not necessarily describe all necessary features of the embodiments of the present invention. The present invention may also be a sub-combination of the features described above.

### BRIEF DESCRIPTION OF THE DRAWINGS

FIG. 1 shows an exemplary configuration of a DA conversion apparatus 100.

FIG. 2 shows an exemplary configuration of the DA converting section 30.

FIG. 3 shows exemplary shift data generated by the data input section 12.

FIG. 4 shows exemplary configurations of the data input section 12 and the DA converting section 30.

FIG. 5 shows exemplary configurations of the M-bit shifter 13 and the decoder circuit 70-1.

FIG. 6A shows exemplary configurations of the N-bit shifter 15, the decoder circuit 70-2, the higher-order inverting section 74, and the lower-order inverting section 76.

FIG. 6B shows an exemplary configuration of a logical OR section 77.

FIG. 7 shows exemplary control of each analog element.

FIG. 8 shows an exemplary configuration of an analog element 60.

FIG. 9 shows an exemplary differential current flowing through the output section 38.

FIG. 10 shows a relationship between an input code of the input digital data Din and an analog level generated according to the first shift data, by using a pattern of the lower-order bit data BSa and the first decoded data (S1 to S15a).

FIG. 11 shows a relationship between an input code of the input digital data Din and an analog level generated according to the first shift data, by using a pattern of the lower-order bit data BSa and the first decoded data (S1 to S15a).

FIG. 12 shows a relationship between an input code of the input digital data Din and an analog level generated according to the first shift data, by using a pattern of the lower-order bit data BSa and the first decoded data (S1 to S15a).

FIG. 13 shows a relationship between an input code of the input digital data Din and an analog level generated according to the second shift data, by using a pattern of the lower-order bit data BSb and the second decoded data (S13b to S15b).

FIG. 14A shows a relationship between an input code of the input digital data Din and an analog level generated according to the second shift data, by using a pattern of the lower-order bit data BSb and the second decoded data (S13b to S15b).

FIG. 14B shows a relationship between an input code of the input digital data Din and an analog level generated according to the second shift data, by using a pattern of the lower-order bit data BSb and the second decoded data (S13b to S15b).

FIG. 15A shows a relationship between an input code of the input digital data Din and an analog level generated according to the second shift data, by using a pattern of the lower-order bit data BSb.

FIG. 15B shows a relationship between an input code of the input digital data Din and an analog level generated according to the second shift data, by using a pattern of the lower-order bit data BSb.

FIG. 16 shows a relationship between an input code of the input digital data Din and a signal level of the output analog signal Sout, by using patterns of the higher-order bit data Sn (S1 to S15), the lower-order bit data BSa, and the lower-order bit data BSb.

FIG. 17 shows a relationship between an input code of the input digital data Din and a signal level of the output analog signal Sout, by using patterns of the higher-order bit data Sn (S1 to S15), the lower-order bit data BSa, and the lower-order bit data BSb.

FIG. 18 shows exemplary combinations of bit shift amounts M and N and the full scale FS(a+b) of the DA converting section 30 for these combinations.

FIG. 19 shows a configuration of a test apparatus 300, along with a device under test 400.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

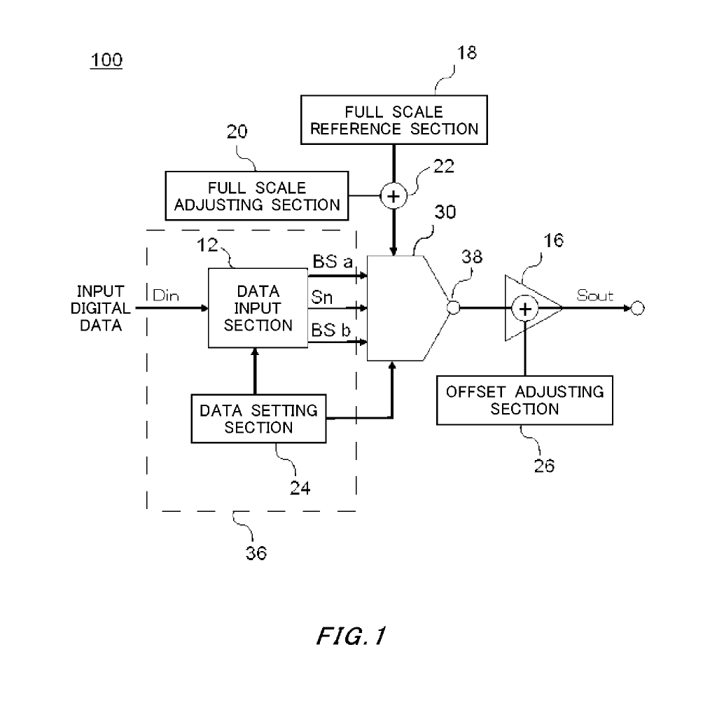

FIG. 1 shows an exemplary configuration of a DA conversion apparatus 100. The DA conversion apparatus 100 converts input digital data Din into an output analog signal Sout, and generates the output analog signal Sout by using a plurality of pieces of shift data obtained by shifting the bits of the input digital data Din. The DA conversion apparatus 100 generates the output analog signal Sout by combining a plurality of analog levels generated according to each piece of shift data. The DA conversion apparatus 100 can change the full scale of the output of the DA conversion apparatus 100, by changing the shift amount of the bits in the shift data. The DA conversion apparatus 100 may determine the bit shift amount according to the full scale that is set. The “full scale of the output” refers to the variable width of the analog level output by the DA conversion apparatus 100 when the digital value of the input digital data Din is changed from a maximum value to a minimum value.

The DA conversion apparatus 100 of the present embodiment includes an analog output section 16, a full scale reference section 18, a full scale adjusting section 20, a reference voltage adding section 22, an offset adjusting section 26, a DA converting section 30, and a control section 36. The DA conversion apparatus 100 may further include a waveform data memory in which input digital data is stored in advance, or an AD converter that outputs the input digital data Din. As another example, the DA conversion apparatus 100 may receive the input digital data from the outside.

The control section 36 includes a data input section 12 and a data setting section 24. The data input section 12 of the present embodiment generates first shift data that is obtained by shifting the input digital data Din by M bits to the right and second shift data that is obtained by shifting the input digital data Din by N bits to the right. Here, M and N are integers greater than or equal to zero.

The data input section 12 inputs to the DA converting section 30 lower-order bit data BSa, lower-order bit data BSb, and higher-order bit data Sn, which are generated based on the first shift data and the second shift data. The lower-order bit data BSa is generated according to prescribed lower-order bits in the first shift data. The lower-order bit data BSb is generated according to prescribed lower-order bits in the second shift data. The higher-order bit data Sn is generated according to prescribed higher-order bits in both the first shift data and the second shift data.

The data setting section 24 may set information concerning the bit shift amounts M and N in advance in the data input section 12. The bit shift amounts M and N may be set in the data setting section 24 by a program provided by a user, for example. The data setting section 24 inputs the set bit shift amounts M and N to the data input section 12. The data setting section 24 controls the DA converting section 30 as described further below.

The DA converting section 30 generates the output analog signal Sout by adding or subtracting an analog level corresponding to the second shift data to or from an analog level corresponding to the first shift data. The DA converting section 30 of the present embodiment generates the output analog signal Sout by combining the analog level corresponding to the lower-order bit data BSa, the analog level corresponding to the lower-order bit data BSb, and the analog level corresponding to the higher-order bit data Sn, which are generated from the first shift data and the second shift data. The data setting section 24 controls whether the analog level corresponding to the second shift data is added to or subtracted from the analog level corresponding to the first shift data. When performing this addition and subtraction control, the data setting section 24 of the present embodiment inverts the bits in portions of the higher-order bit data Sn and the lower-order bit data BS corresponding to the second shift data.

There are a plurality of analog elements controlled by the lower-order bit data BSa, a plurality of analog elements controlled by the lower-order bit data BSb, and a plurality of analog elements controlled by the higher-order bit data Sn. Each analog element outputs an analog level corresponding to the results of the control. The DA converting section 30 generates the output analog signal Sout by combining the analog levels output by each of the analog elements.

As an example, for the analog elements controlled by the lower-order bit data BS, the variable widths of the analog levels that can be output increase in a binary manner with respect to each other. Furthermore, for the analog elements controlled by the higher-order bit data Sn, the variable widths of the analog levels that can be output are substantially the same. The variable widths of the analog levels of the analog elements controlled by the higher-order bit data Sn is greater than the variable widths of the analog levels that can be generated by the analog elements controlled by the lower-order bit data BS.

In the DA converting section 30, the analog elements controlled by the higher-order bit data Sn can be controlled by the higher-order bits in the first shift data or the second shift data. Therefore, the ability to change the analog level of the output analog signal Sout in small variable steps is preserved, while also allowing for a reduction in the circuit size. The output section 38 outputs the output analog signal Sout generated by the DA converting section 30. The output section 38 may be an output terminal in the DA converting section 30.

The full scale reference section 18 outputs a reference voltage that determines a reference of the full scale of the output analog signal Sout output by the output section 38. For example, the DA converting section 30 may generate the output analog signal Sout by dividing the reference level according to the input bit data. The full scale adjusting section 20 outputs an adjustment voltage for slightly adjusting the reference voltage. The reference voltage adding section 22 adds or subtracts the adjustment voltage to or from the reference voltage output by the full scale reference section 18, and inputs the resulting voltage to the DA converting section 30.

The analog output section 16 performs a prescribed process on the output analog signal Sout output by the output section 38, and outputs the resulting signal. The analog output section 16 of the present embodiment adds or subtracts a prescribed offset level to or from the signal level of the output analog signal Sout. The offset adjusting section 26 supplies the analog output section 16 with an offset voltage. The analog output section 16 may amplify or attenuate the output analog signal Sout, and output the resulting signal.

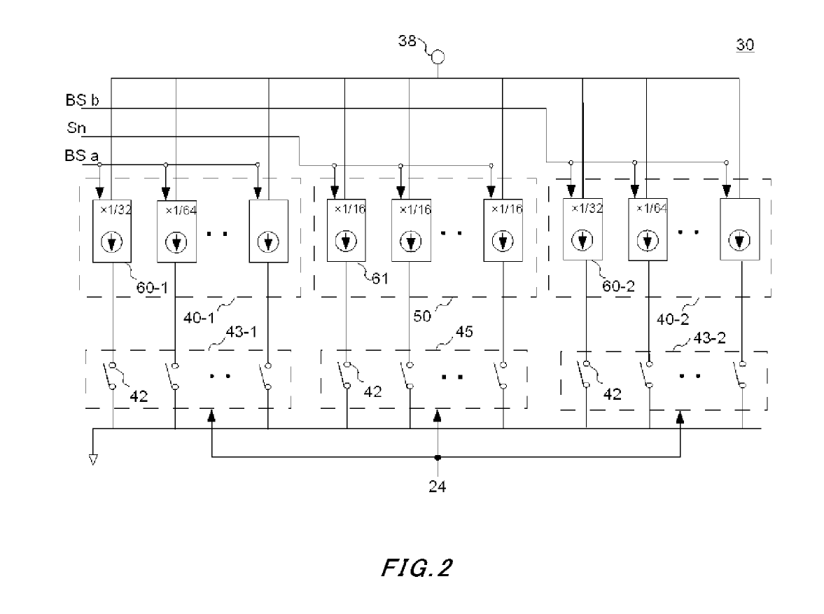

FIG. 2 shows an exemplary configuration of the DA converting section 30. The DA converting section 30 includes an output section 38, a first binary section 40-1, a segment section 50, a second binary section 40-2, a first binary disabling section 43-1, a segment disabling section 45, and a second binary disabling section 43-2. The plurality of analog elements included in the DA converting section 30 are divided among the first binary section 40-1, the segment section 50, and the second binary section 40-2. The output section 38 is connected to each analog element and combines the analog levels output by each analog element.

The first binary section 40-1 and the second binary section 40-2 each include a plurality of analog elements 60. The first analog elements 60-1 in the first binary section 40-1 are provided to correspond to the bits of the lower-order bit data BSa. The second analog elements 60-2 in the second binary section 40-2 are provided to correspond to the bits of the lower-order bit data BSb. Each analog element 60 outputs an analog level corresponding to the value of the corresponding bit in the lower-order bit data BS.

The change amount in the analog level received by each first analog element 60-1, i.e. the variable width of the analog level output by the first analog element 60-1, increases in a binary manner among the first analog elements 60-1. The change amount in the analog level received by each second analog element 60-2, i.e. the variable width of the analog level output by the second analog element 60-2, increases in a binary manner among the second analog elements 60-2. Each binary section 40 in the present embodiment has a plurality of analog elements 60 for which the output level when the corresponding bit in the lower-order bit data BS is 1 changes by 1/32, 1/64, etc. of the reference level. Furthermore, in the present embodiment, when the corresponding bit of the lower-order bit data BS is 0, the output level of the analog element 60 is 0 times the reference level. The reference level may be the reference voltage provided from the reference voltage adding section 22.

In other words, each analog element 60 in the present embodiment outputs an analog level that is ½^{P} times the reference level when the corresponding bit in the lower-order bit data BS is 1, and outputs an analog level that is 0 times the reference level when the corresponding bit in the lower-order bit data BS is 0. Here, p indicates the digit position of the corresponding bit in the lower-order bit data BS. In this way, each binary section 40 outputs an analog level that changes in a binary manner according to the lower-order bit data BS.

The segment section 50 includes two or more common analog elements 61 that are provided in common for the first shift data and the second shift data. The common analog elements 61 of the present embodiment are controlled by the higher-order bit data Sn generated from the higher-order bits of both the first shift data and the second shift data. If the higher-order bit data Sn is generated from the upper k bits of both the first shift data and the second shift data, the higher-order bit data Sn is data that is coded in segments of 2^{k}-1 bits. In this case, the segment section 50 includes 2^{k}-1 common analog elements 61. Each common analog element 61 is controlled by a value of the corresponding bit in the higher-order bit data Sn.

The change amounts in the analog levels received by the common analog elements 61 in the segment section 50, i.e. the variable width of the analog levels output by the common analog elements 61, are the same. The variable width of the analog level of each common analog element 61 is two times the variable width of the analog element 60 having the largest variable width of an analog signal among the analog elements 60 in the binary section 40. Each common analog element 61 in the present embodiment outputs an analog level that is 1/16 of the reference level when the corresponding bit in the higher-order bit data Sn is 1. Furthermore, each common analog element 61 outputs an analog level that is 0 times the reference level when the corresponding bit in the higher-order bit data Sn is 0.

The control section 36 has at least two control states including a first control state, in which the common analog elements 61 are controlled according to the higher-order bits of the first shift data, and a second control state, in which the common analog elements 61 are controlled according to the higher-order bits of the second shift data. In the present example, for each common analog element 61, the “first control state” refers to the control state in which the corresponding bit in the higher-order bit data Sn can be generated based on only the higher-order bits of the first shift data, from among the higher-order bits of the first shift data and the higher-order bits of the second shift data. In other words, the bits of the first control state in the higher-order bit data Sn are not affected by the higher-order bits of the second shift data. Furthermore, the “second control state” refers to the control state in which the bits in the higher-order bit data Sn are generated based on only the higher-order bits of the second shift data, from among the higher-order bits of the first shift data and the higher-order bits of the second shift data. The bits of the second control state in the higher-order bit data Sn are not affected by the higher-order bits of the first shift data. The control section 36 can select the second control state for only a portion of the common analog elements 61, and need not be able to select the second control state for other common analog elements 61.

The control state for each common analog element 61 changes according to the bit shift amounts M and N in the control section 36. The control section 36 determines whether each bit in the higher-order bit data Sn is in the first control state or the second control state, based on the bit shift amounts M and N.

In the control section 36, the control state for each common analog element 61 is determined such that more common analog elements 61 are allocated to shift data with a smaller bit shift amount. In other words, the shift data with a large bit shift amount has a small variable width for the values of the higher-order bits, and therefore an analog level corresponding to these higher-order bits can be generated by a small number of common analog elements 61.

The data setting section 24 preferably limits the bit shift amounts M and N according to the number of common analog elements 61. For example, when the bit shift amount is 0 in one of the sets of shift data, all of the common analog elements 61 are allocated to this shift data, and therefore the data setting section 24 increases the bit shift amount for the other shift data such that there is no need to allocate common analog elements 61 to this other shift data.

Each disable section switches whether the corresponding analog element is in a disabled control state. The “disabled control state” is a state in which the analog element does not consume power regardless of the value of the corresponding bits in the higher-order bit data Sn and the lower-order bit data BS. For example, when in the disabled control state, the analog element is cut off from the power supply.

Each disable section in the present embodiment includes a cutoff switch 42 for each corresponding analog element. Each cutoff switch 42 switches whether the corresponding analog element is connected to a power supply line (or a ground line).

The control section 36 has, in addition to the first control state and the second control state described above, the disable state in which a common analog element 61 is controlled to be in the disabled control state. The disabled control state for each common analog element 61 changes according to the bit shift amounts M and N. In the present embodiment, the data setting section 24 controls the cutoff switch 42 corresponding to a common analog element 61 in the disabled control state to be in the OFF state.

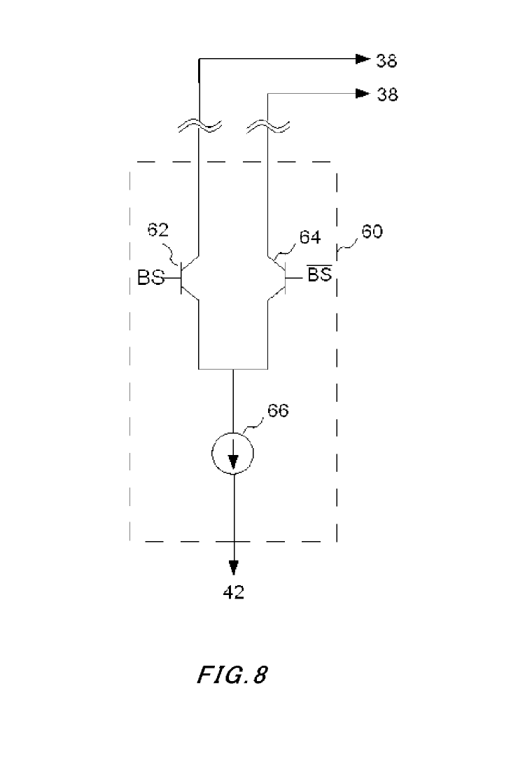

The data setting section 24 controls common analog elements 61 that are not controlled according to the first shift data or the second shift data by the bit shift in the data input section 12, from among the plurality of common analog elements 61, to be in the disabled control state. A specific example of the control section 36 applying one of the first control state, the second control state, and the disabled control state to each common analog element 61 is described in detail further below with reference to FIG. 9.

The data setting section 24 may control the analog elements 60 in each binary section 40 to be in the disabled control state based on the bit shift amounts M and N. For example, the data setting section 24 may set analog elements 60 for which the corresponding bit of the shift data is an empty bit to be in the disabled control state, from among the analog elements 60 included in the binary sections 40.

Instead of controlling each analog element to be in the disabled control state, the control section 36 may control these analog elements to be always ON. By providing analog elements that are controlled to be in the always ON state, the offset level of the output analog signal can be set. For example, the control section 36 may set the offset level such that analog level output by the DA converting section 30 when the input code of the input digital data Din is a middle value approaches the 50% level of the waveform amplitude of the expected output analog signal.

All or some of the second analog elements 60-2 in the second binary section 40-2 may be replaced with segmented analog elements 60 that have the same output level as each other, instead of being analog elements 60 with output levels that change in a binary manner with respect to each other. In this case, the data input section 12 further includes a decoder that decodes all or a portion of the lower-order bit data BSb into segment data. In the manner described above, the control section 36 may control the second analog elements 60-2 that are not controlled by the second shift data, to be in the always ON state. In this way, a variety of offset levels can be set.

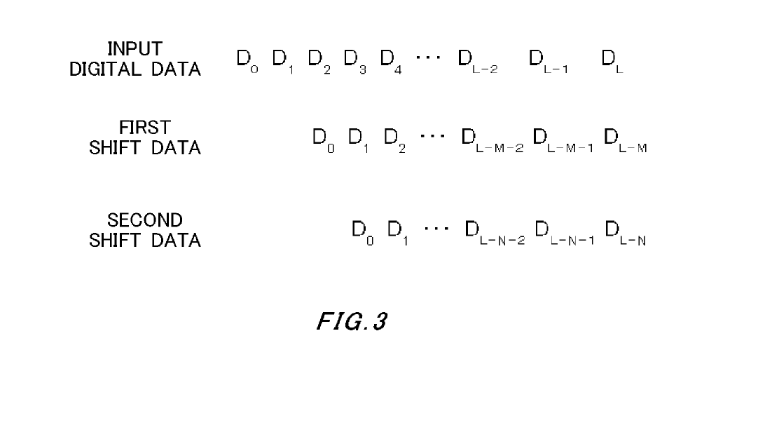

FIG. 3 shows exemplary shift data generated by the data input section 12. The data input section 12 of the present embodiment receives input digital data Din including L bits. The data input section 12 generates first shift data by shifting the input digital data Din to the right by M bits, and second shift data by shifting the input digital data Din to the right by N bits.

The first shift data and the second shift data include empty bits as the top M bits or N bits, as a result of the bit shift to the right. The data input section 12 inserts prescribed bits into these empty bits. For example, the data input section 12 may insert a value of 0 into the empty bits. If the input digital data Din is expressed by two complementing codes, most significant bit (MSB) information of the input digital data may be inserted into the empty bits. In this way, the waveform and offset voltage are maintained, and the signal amplitude can be changed.

If the input digital data Din is expressed by an offset binary code or straight binary code, the MSB of the input digital data Din is fixed and the second MSB and onward may be shifted to the right. Information of a bit obtained by inverting the MSB of the input digital data Din is then inserted into the empty bits. In this way, the waveform and offset voltage are maintained, and the signal amplitude can be changed. The direction of the bit shift performed by the data input section 12 of the present invention is to the right, but a bit shift to the left may be performed for at least one set of shift data.

The data input section 12 generates the higher-order bit data Sn from predetermined upper k bits in both the first shift data and the second shift data. These upper k bits include empty bits caused by the bit shift by the data input section 12. For example, in the example shown in FIG. 3, the upper k bits in the first shift data include M empty bits and the bits D₀ to D_{k-M}. The upper k bits in the second shift data include N empty bits and the bits Dₒ to D_{k-N}.

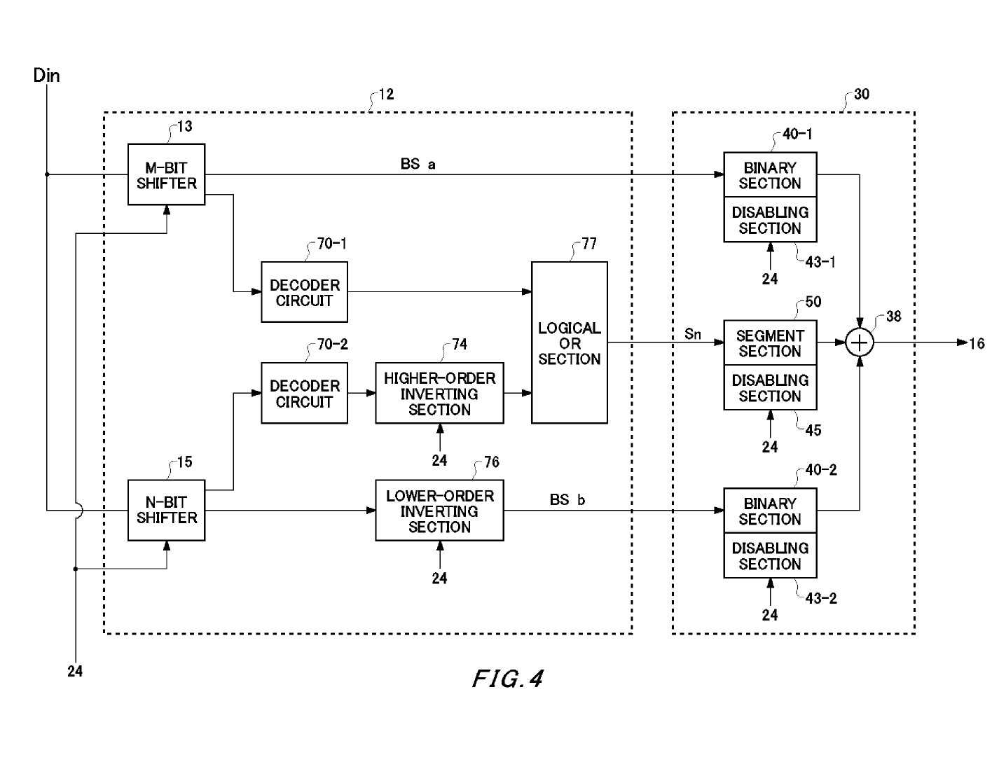

FIG. 4 shows exemplary configurations of the data input section 12 and the DA converting section 30. The DA converting section 30 is the same as the DA converting section 30 shown in FIG. 2. The data input section 12 includes an M-bit shifter 13, an N-bit shifter 15, two decoder circuits 70-1 and 70-2 (referred to collectively as the “decoder circuits 70”), a logical OR section 77, a higher-order inverting section 74, and a lower-order inverting section 76.

The M-bit shifter 13 receives the input digital data Din and generates the first shift data by shifting the input digital data Din by M bits to the right. The M-bit shifter 13 inputs to the decoder circuit 70-1 a predetermined number of higher-order bits (k bits in this example) of the first shift data. The M-bit shifter 13 inputs to the binary section 40-1, as the lower-order bit data BSa, the remaining lower-order bits of the first shift data.

The N-bit shifter 15 receives the input digital data Din and generates the second shift data by shifting the input digital data Din by N bits to the right. The N-bit shifter 15 inputs to the decoder circuit 70-2 a predetermined number of higher-order bits (k bits in this example) of the second shift data. The N-bit shifter 15 inputs to the lower-order inverting section 76 the remaining lower-order bits of the second shift data.

The lower-order inverting section 76 controls whether the sign of the lower-order bit data in the second shift data is inverted. Inversion of the sign refers to converting a bit from 1 to 0 or from 0 to 1, for example. The data setting section 24 causes the lower-order inverting section 76 to invert the sign of the lower-order bits of the second shift data when generating an analog level obtained by subtracting the analog level corresponding to the second shift data from the analog level corresponding to the first shift data. The data setting section 24 does not cause the lower-order inverting section 76 to invert the sign of the lower-order bits of the second shift data when generating an analog level obtained by adding the analog level corresponding to the second shift data to the analog level corresponding to the first shift data. The output of the lower-order inverting section 76, which is the lower-order bits of the second shift data that are either inverted or not inverted, is input to the second binary section 40-2 as the lower-order bit data BSb.

The decoder circuit 70-1 outputs first decoded data obtained by decoding the upper k bits of the first shift data into data of 2^{k}-1 bits. The number of digits (number of bits) in the first decoded data is the same as the number of common analog elements 61 provided in the segment section 50. The decoder circuit 70-1 of the present embodiment generates the first decoded data including 2^{k}-1 bits, wherein the number of bits showing a value of 1 is equal to the value obtained by converting the upper k bits of the first shift data into decimal digits and the other bits show a value of 0. In the same way, the decoder circuit 70-2 outputs the second decoded data obtained by decoding the upper k bits of the second shift data. If M is less than or equal to N, the number of empty bits in the second shift data is greater than the number of empty bits in the first shift data. When generating the logical OR data of the first shift data and the second shift data, the empty bits do not affect the logical OR data, and therefore the decoder circuit 70-2 may generate the second decoded data by decoding only the effective bits, i.e. the bits that are not empty bits, from among the upper k bits in the second shift data.

The higher-order inverting section 74 controls whether the sign of the second decoded data output by the decoder circuit 70-2 is inverted. The data setting section 24 causes the higher-order inverting section 74 to invert the sign of the second decoded data when generating an analog level by subtracting the analog level corresponding to the second shift data from the analog level corresponding to the first shift data. The data setting section 24 does not cause the higher-order inverting section 74 to invert the sign of the second decoded data when generating an analog level by adding the analog level corresponding to the second shift data to the analog level corresponding to the first shift data. The logical OR section 77 outputs, as the higher-order bit data Sn, the logical OR of the first decoded data output by the decoder circuit 70-1 and the second decoded data output by the higher-order inverting section 74. The number of digits (number of bits) in the higher-order bit data Sn is the same as the number of common analog elements 61 provided in the segment section 50.

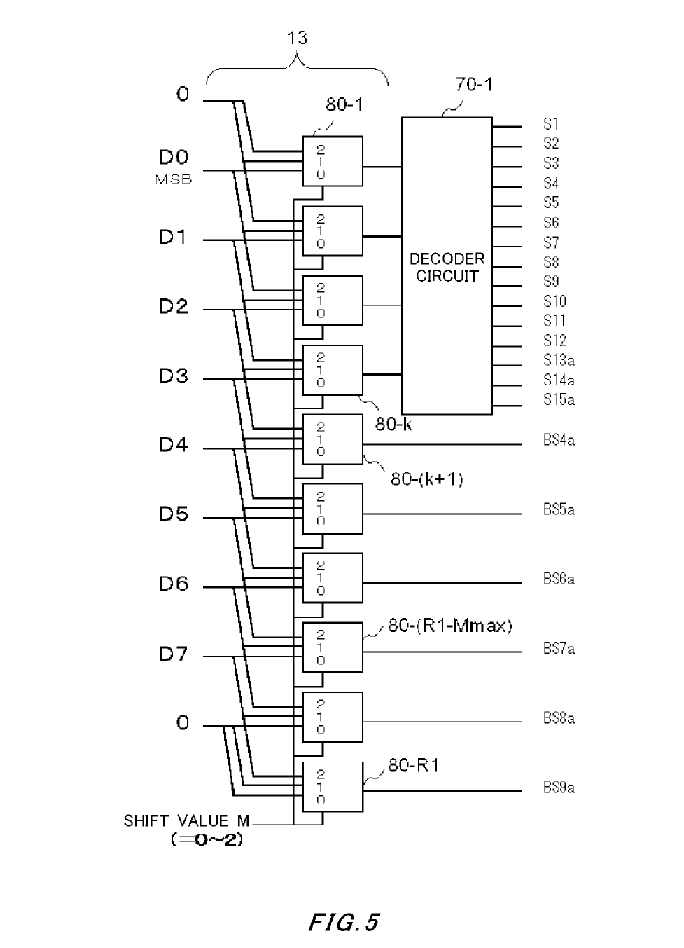

FIG. 5 shows exemplary configurations of the M-bit shifter 13 and the decoder circuit 70-1. The present embodiment describes an example using the M-bit shifter 13 that performs a 0 to 2 bit shift, but the bit shift amount M of the M-bit shifter 13 may be a different value.

The M-bit shifter 13 of the present embodiment includes R1 selectors 80. Here, it is preferable that R1=L+Mmax. In this case, the DA converting section 30 does not suffer a drop in waveform resolution due to the M-bit shift. However, if a drop in waveform resolution due to the M-bit shift in the DA converting section 30 is allowable, it is possible for R1<L+Mmax. Here, L is the number of bits in the input digital data Din, and Mmax is the maximum bit shift amount in the M-bit shifter 13. In the example shown in FIG. 5, R1=L+Mmax, L=8, and Mmax=2. The minimum unit for the change amount in the analog level received by an analog element 60-1 in the first binary section 40-1 is (½)^{R1} times the reference level.

The L selectors 80-1 to 80-(R1-Mmax) are provided to correspond one-to-one with the bits (D₀ to D₇) of the input digital data. The selector 80-r (where r is an integer from 1 to (R1-Mmax)) selects and outputs the corresponding bit (Dᵣ₋₁) of the input digital data Din when the bit shift amount M is 0. Furthermore, the selector 80-r selects and outputs the bit (Dᵣ₋₂) that is one bit higher in the input digital data Din when the bit shift amount M is 1. The selector 80-r selects and outputs the bit (Dᵣ₋₃) that is two bits higher in the input digital data Din when the bit shift amount M is 2. If there is no higher bit that can be selected, the selector 80-r selects and outputs a bit with a value of 0.

The R1-L (in this example, R1-L=Mmax) selectors 80-s (where s is an integer from L+1 to R1) that are not included among the L selectors 80 select and output a bit with a value of 0 when the bit shift amount M is 0. The selector 80-s selects and outputs the bit (Dₛ₋₂) that is one bit higher in the input digital data Din when the bit shift amount M is 1. The selector 80-s selects and outputs the bit (Dₛ₋₂) that is two bits higher in the input digital data Din when the bit shift amount M is 2. If there is no higher bit that can be selected, the selector 80-s selects and outputs a bit with a value of 0. If R1<L+Mmax, it is possible that there is no selector 80 that selects a lower-order bit in the input digital data as a result of the value of the bit shift amount M. In this case, the information of this lower-order bit is not used when generating the analog level for this bit shift amount M, and therefore the waveform resolution drops as described above.

The decoder circuit 70-1 converts the k bits of data output by the upper k selectors 80-1 to 80-k into the first decoded data (S1 to S15a) including 2^{k}-1 bits. The number of bits in the first decoded data is the same as the number of common analog elements 61. In the present example, k=4.

Here, in the first decoded data, a number of bits equal to the value obtained when the k-bit data output by the k selectors 80-1 to 80-k is converted into decimal digits have values of 1 in order from the Si side. For example, when the bit output by the selector 80-v (where v is from 1 to k) is By, the value obtained when the k-bit data is converted to decimal digits is as shown below.

B₁×2^{k-1}+B₂×2^{k-2}+. . . +Bₖ×2⁰

Accordingly, in the example shown in FIG. 5 where k=4, when the bit shift amount M is 1 or more, for example, B₁ is 0, and therefore the decimal digit value described above has a maximum of 7. In other words, the logic value of the bits S13a, S14a, and S15a in the first decoded data is always 0 when the bit shift amount M is 1 or more. As described further below, the higher-order bit data Sn is generated from the logical OR of the first decoded data and the second decoded data, and therefore the bits S13, S14, and S15 of the higher-order bit data Sn corresponding to the bits S13a, S14a, and S15a are affected by the bits S13a, S14a, and S15a of the first decoded data, but when the bit shift amount M is 1 or more, the control state for the common analog elements 61 corresponding to the bits S13, S14, and S15 of the higher-order bit data Sn is the second control state, which is unaffected by the bits S13a, S14a, and S15a of the first decoded data. Furthermore, in the present embodiment, the common analog elements 61 corresponding to the bits S1 to S12 of the higher-order bit data Sn are fixed in the first control state.

The M-bit shifter 13 outputs, as the lower-order bit data BSa, the (R1−k)-bit data (in this example, BS4a to BS9a) output by the lower R1−k selectors 80-(k+1) to 80-R1.

The higher bits in the lower-order bit data BSa control the first analog elements 60-1 having greater variable widths. For ease of explanation, the lower M bits in the input digital data Din in the example of FIG. 3 are not included in the first shift data, and the M-bit shifter 13 outputs the lower-order bit data BSa including the lower M bits of the input digital data Din.

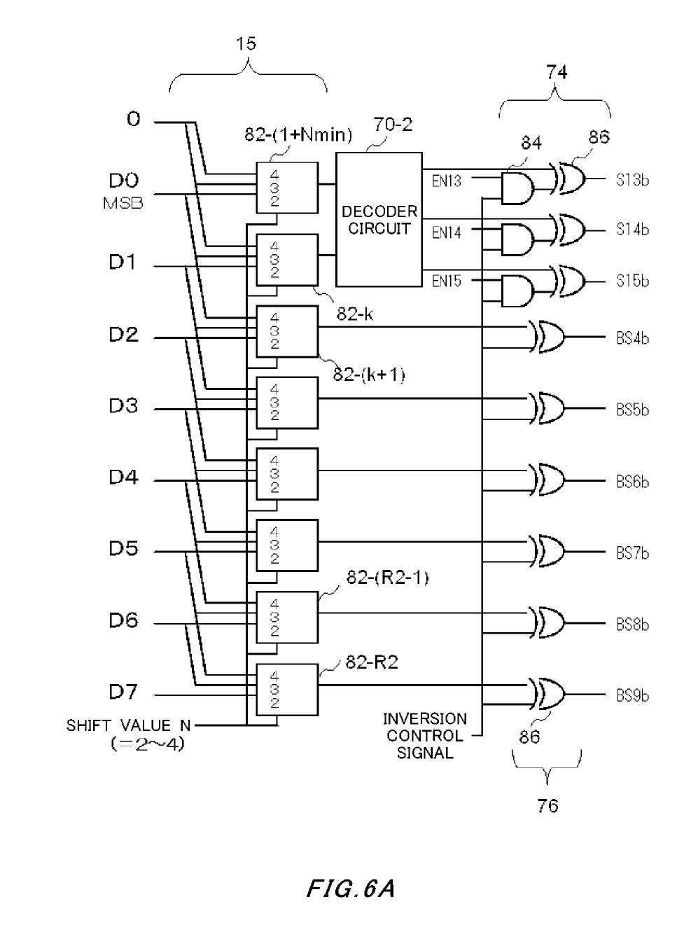

FIG. 6A shows exemplary configurations of the N-bit shifter 15, the decoder circuit 70-2, the higher-order inverting section 74, and the lower-order inverting section 76. The present embodiment describes an example using an N-bit shifter 15 that performs a shift of two to four bits, but the bit shift amount N for the N-bit shifter 15 may be another value. However, the possible setting ranges of the bit shift amounts for the M-bit shifter 13 and the N-bit shifter 15 are preferably determined such that M is always less than or equal to N.

The N-bit shifter 15 in the present embodiment includes R2-Nmin selectors 82. Here, it is preferable that R2=L+Nmax. In this case, the DA converting section 30 does not experience a drop in waveform resolution due to the N-bit shift. However, if a drop in waveform resolution of the DA converting section 30 due to the N-bit shift is allowable, it is possible for R2<L+Nmax. Here, Nmin is the minimum bit shift amount in the N-bit shifter 15, and Nmax is the maximum bit shift amount in the N-bit shifter 15. In the example shown in FIG. 6A, R2=L+Nmin, Nmin=2, Nmax=4, and L=8. The minimum unit for the change amount in the analog level received by an analog element 60-2 in the second binary section 40-2 is (½)^{R2} times the reference level.

In the present embodiment, the L selectors 82-(1+Nmin) to 82-R2 are provided to correspond one-to-one with the bits (D₀ to D₇) of the input digital data. The selector 82-t (where t is an integer from 1+Nmin to R2) selects and outputs the corresponding bit (D_{t-1-Nmin}) of the input digital data Din when the bit shift amount N is 2. Furthermore, the selector 82-t selects and outputs the bit (D_{t-2-Nmin}) that is one bit higher in the input digital data Din when the bit shift amount N is 3. The selector 82-t selects and outputs the bit (D_{t-3-Nmin}) that is two bits higher in the input digital data Din when the bit shift amount N is 4. If there is no higher bit that can be selected, the selector 82-t selects and outputs a bit with a value of 0. In the present embodiment, a bit value of 0 is input to the upper k-Nmin selectors 82.

The decoder circuit 70-2 converts the k-Nmin bits of data output by the upper k-Nmin selectors 82-(1+Nmin) to 82-k into the second decoded data (S13b to S15b) including 2^{(k-Nmin)}-1 bits. In the second decoded data, a number of bits equal to the value obtained when the (k-Nmin)-bit data output by the k-Nmin selectors 82-(1+Nmin) to 82-k is converted into decimal digits have values of 1 in order from the S15b side. For example, when the bit output by the selector 82-w (where w is from 1+Nmin to k) is Bw, the value obtained when the (k-Nmin)-bit data is converted to decimal digits is as shown below.

B_{1+Nmin}×2^{k-Nmin-1}+B_{2+Nmin}×2^{k-Nmin-2}+. . . +Bₖ×2⁰

Accordingly, in the example shown in FIG. 6A, when the bit shift amount N is 4, for example, B_{1+Nmin} and Bₖ are 0, and therefore the decimal digit value is 0. In other words, the logic value of the bits S13b, S14b, and S15b in the second decoded data is always 0 when the bit shift amount N is 4. When the bit shift amount N is 4, the control state for the common analog elements 61 corresponding to the bits S13, S14, and S15 of the higher-order bit data Sn is the first control state. For other values of the bit shift amount N, the common analog elements 61 corresponding to the bits S13, S14, and S15 of the higher-order bit data Sn have their control states limited, in the same manner as described in relation to FIG. 5. In this way, the control state for each common analog element 61 is switched according to the bit shift amount M and the bit shift amount N.

The higher-order inverting section 74 switches whether the sign of the first decoded data output by the decoder circuit 70-2 is inverted. The higher-order inverting section 74 of the present embodiment includes AND circuits 84 and EOR circuits 86 provided to correspond one-to-one with the bits of the second decoded data.

Each AND circuit 84 outputs the logical AND of an enable signal (EN13 to EN15) and an inversion control signal. The inversion control signal has a value of 0 when the sign is not to be inverted, and has a value of 1 when the sign is to be inverted. The enable signals are set respectively for each bit of the second decoded data. The upper k-Nmin selectors 82-(1+Nmin) to 82-k select a bit value of 0 to be input separately from the input digital data Din, and therefore each enable signal is set to a value of 0 when the corresponding bit of the second decoded data is 0 and set to 1 in all other cases. In other words, since a bit value of 0 is selected for input independently of the input digital data Din, when the corresponding bit in the second decoded data is 0, this bit in the second decoded data is not used to control the common analog element 61. However, if the AND circuits 84 are not provided, when a value of 1 is input as the inversion control signal, bits that are not intended to be used in the second decoded data have a value of 1.

Each EOR circuit 86 outputs a logical EOR of the corresponding bit in the second decoded data and the corresponding AND circuit 84. In this way, each bit in the second decoded data can be inverted or not inverted according to the inversion control signal.

The lower-order inverting section 76 includes EOR circuits 86 provided to correspond one-to-one with the lower selectors 82-(k+1) to 82-R2. Each EOR circuit 86 outputs the logical EOR of the bit output by the corresponding selector 82 and the inversion control signal. In this way, each bit in the lower-order bit data BSb (in this example, BS4b to BS9b) can be inverted or not inverted according to the inversion control signal.

FIG. 6B shows an exemplary configuration of a logical OR section 77. The logical OR section 77 of the present embodiment includes OR circuits 88 provided to correspond one-to-one with the bits of the second decoded data. Each OR circuit 88 outputs the logical OR of the corresponding bit of the first decoded data and the corresponding bit of the second decoded data. In the present embodiment, the common analog elements 61 corresponding to the higher-order bit data S1 to S12 are fixed in the first control state, and therefore the logical OR section 77 generates the logical OR of the bits S13a to S15a of the first decoded data and the bits S13b to S15b of the second decoded data. The logical OR section 77 may output, as the bits of the higher-order bit data Sn, the bits in the first decoded data that do not correspond to the second decoded data (in this example, S1 to S12) and the logical OR values output by the OR circuits 88 (S13 to S15).

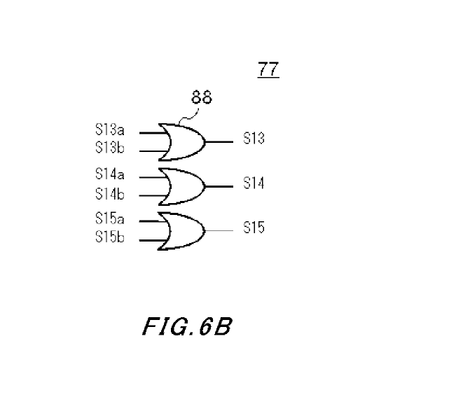

FIG. 7 shows exemplary control of each analog element. As described above, the segment section 50 includes 2^{k}-1 common analog elements 61 that are controlled according to the higher-order bit data Sn. In this example, k=4.

The following description assumes that the bit shift amount N is greater than or equal to the bit shift amount M, but since the first shift data and the second shift data have the same properties, this assumption does not prevent a more general understanding. When the bit shift amount M of the first shift data is 0, the higher-order bits of the first shift data are D₀D₁D₂D₃, and the values of these bits change in a decimal digit range from 0 to 15. In the present embodiment, when the bit shift amount M is 0, the control state for all 15 of the common analog elements 61 included in the segment section 50 is the first control state. In other words, the first shift data is allocated to all of the common analog elements 61, and the second shift data is not allocated to any of the common analog elements 61. Therefore, the bit shift amount N of the second shift data is set to be 4 or more.

When the bit shift amount M of the first shift data is 1, the higher-order bits of the first shift data, excluding empty bits, are D₀D₁D₂, and the values of these bits change within a decimal digit range from 0 to 7. In this case, the control state for seven of the common analog elements 61 included in the segment section 50 is the first control state, and the first shift data is allocated to these common analog elements 61. Therefore, the remaining eight common analog elements 61 of the segment section 50 can be allocated to the second shift data. When the bit shift amount of the first shift data is 2 or more, the number of common analog elements 61 allocated to the first shift data becomes even lower.

Since N is greater than or equal to M, when M is 1 or more, the number of common analog elements 61 controlled according to the second shift data is a maximum of seven, and this is less than the number of common analog elements 61 that are not allocated to the first shift data. Accordingly, when the bit shift amount M is 1 or more, any bit shift amount N other than 0 can be set.

For example, when M=1 and N=2, the first shift data is allocated to seven of the common analog elements 61 in the segment section 50, and the second shift data is allocated to three of the common analog elements 61. In this case, the remaining five common analog elements 61 in the segment section 50 are not controlled by either set of shift data. As described above, the data setting section 24 controls these five common analog elements 61 to be in the disabled control state.

As another example, when M=3 and N=4, the first shift data is allocated to one of the common analog elements 61 in the segment section 50. In this case, the remaining fourteen common analog elements 61 in the segment section 50 are not controlled by either set of shift data. As described above, the control section 36 controls these fourteen common analog elements 61 to be in the disabled control state.

When one of the bit shift amount M and the bit shift amount N is 0, the data input section 12 of the present embodiment generates the shift data such that the other bit shift amount is k or more. If neither the bit shift amount M nor the bit shift amount N are 0, there is no restriction on the setting of the bit shift amounts.

The control section 36 determines whether to control each common analog element 61 in the segment section 50 to be in the first control state, the second control state, or the disabled control state, based on the bit shift amounts M and N. For example, the control section 36 can switch the control state of these common analog elements 61 using the configuration shown in FIGS. 4 to 6B.

In this way, by providing the segment section 50 with shared first shift data and second shift data and setting the bit shift amount according to prescribed conditions, the circuit size of the DA converting section 30 can be decreased. Furthermore, by setting analog elements that are not being controlled to the disabled control state, the power consumption can be decreased.

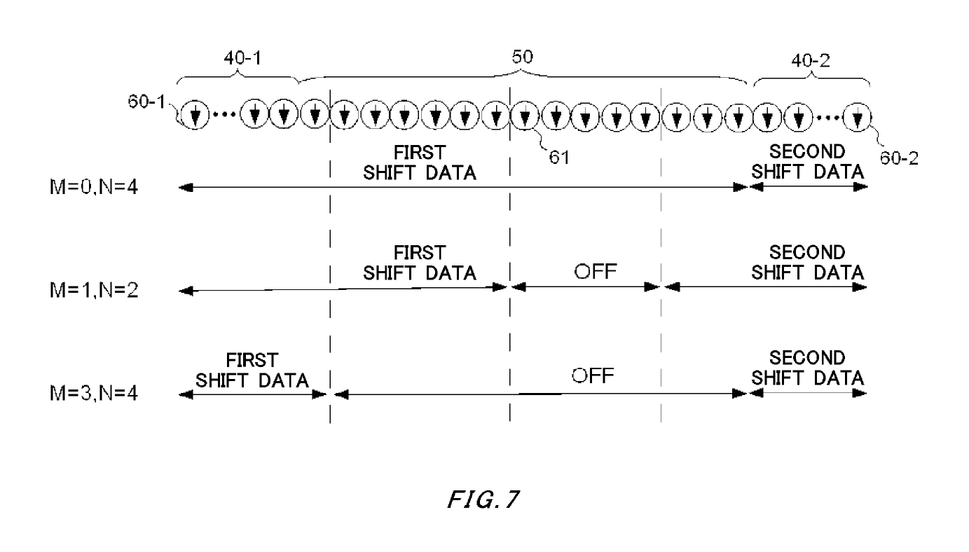

FIG. 8 shows an exemplary configuration of an analog element 60. The common analog elements 61 may have the same configuration as the analog element 60. The analog element 60 of the present embodiment includes a positive transistor 62, a negative transistor 64, and a current source 66. The current source 66 is provided between the cutoff switch 42 and the transistors.

A differential control level corresponding to the corresponding bits of the lower-order bit data BS is applied to the positive transistor 62 and the negative transistor 64. In the common analog elements 61, a differential control level corresponding to the corresponding bits of the higher-order bit data Sn is applied instead. The emitter terminals of the positive transistor 62 and the negative transistor 64 are connected to the current source 66. In this way, differential current flows through the collector terminals of the positive transistor 62 and the negative transistor 64.

The collector terminals of the positive transistor 62 and the negative transistor 64 are connected to the output section 38 by differential signal lines. In FIG. 2, these differential signal lines are shown as a single line. Current equal to the sum of the current flowing through each analog element flows through the output section 38. The output section 38 converts this summed current into voltage by passing the current through a prescribed resistance.

FIG. 9 shows an exemplary differential current flowing through the output section 38. In FIG. 9, the horizontal axis represents time and the vertical axis represents the current value. Furthermore, in FIG. 9, the positive current is shown by a solid line and the negative current is shown by a dotted line. The present embodiment describes an example using input digital data with a sinusoidal waveform. As described above, a differential current flows through each analog element, and therefore current in which the positive and negative portions cross each other flows through the output section 38.

However, in the DA converting section 30 of the present embodiment, the analog elements are controlled according to shift data in which the bits are shifted to the right, and therefore there are analog elements that are not controlled according to either type of shift data. In this case, only a positive current or a negative current flow through these analog elements, without changing the control level of the analog element. Therefore, the current flowing through the output section 38 results from shifting only the positive or the negative current, which does not result in a differential signal.

For example, in a case where analog elements including current sources 66 of 1 mA, 2 mA, and 4 mA operate differentially and an analog element including a current source 66 of 8 mA has only negative current flowing therethrough, the negative current is shifted by 8 mA, as shown in FIG. 9. To solve this problem, the DA converting section 30 sets analog elements that are not controlled by either set of shift data to be in the disabled control state, thereby preventing this shift caused by the current from an analog element that is not controlled by either set of shift data. As a result, a signal operating differentially can be generated. Furthermore, by eliminating the power consumption of the analog elements in the disabled control state, low overall power consumption can be realized.

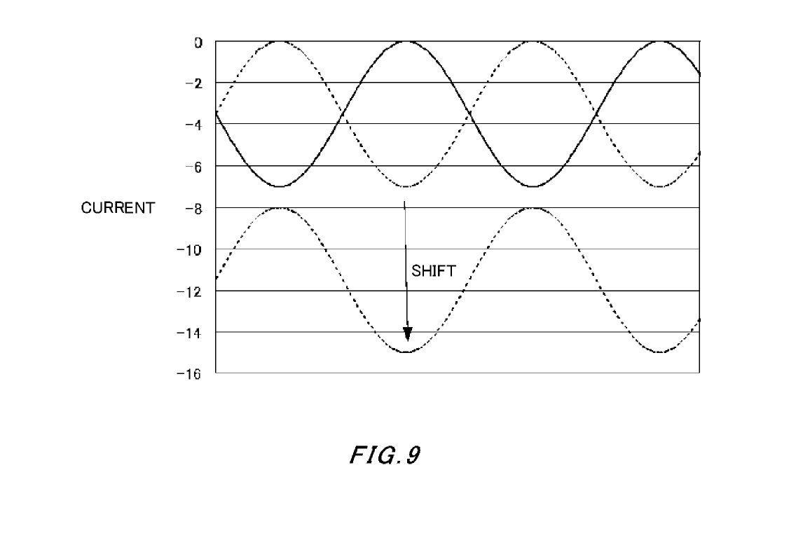

FIG. 10 shows a relationship between an input code of the input digital data Din and an analog level generated according to the first shift data, by using a pattern of the lower-order bit data BSa and the first decoded data (S1 to S15a). In FIG. 10, the horizontal axis represents the input code of the input digital data Din, and the vertical axis represents the analog level generated according to the first shift data. In FIG. 10, the magnitude of the analog level for each input code is shown by diagonal lines. Here, each input code corresponds to the value obtained by converting the input digital data Din into decimal digits.

The following describes an example in which M=0, L=8, and k=4. Furthermore, each box in FIG. 10 filled with diagonal lines indicates that the corresponding bit in the first decoded data has a value of 1, and each box that is filled with white indicates that the corresponding bit in the first decoded data has a value of 0. Furthermore, the change pattern of the value of BSa for the input code is shown by triangles filled with diagonal lines.

In this example, the change pattern of BSa changes with a period of 2⁴=16, with the value of the input code as a variable. The value of the lower-order bit data BSa in each cycle increases along with the increase of the input code value. The change pattern of BSa changes with a period of 2^{(L-k+M)}, with the value of the input code as a variable.

The number of bits having a value of 1 in the first decoded data increase by one every time the input code value increases by 2^{(L-k+m)}. In the example shown in FIG. 10, the number of bits having a value of 1 in the first decoded data increases by one every time the input code value increases by 16.

As shown in FIG. 10, when M=0, there is a change from a state in which all of the common analog elements 61 are OFF to a state in which all of the common analog elements 61 are ON, according to the increase in the input code. The variable width (full scale) of the analog level generated according to the first shift data when M=0 is set to be FS_a=1.0.

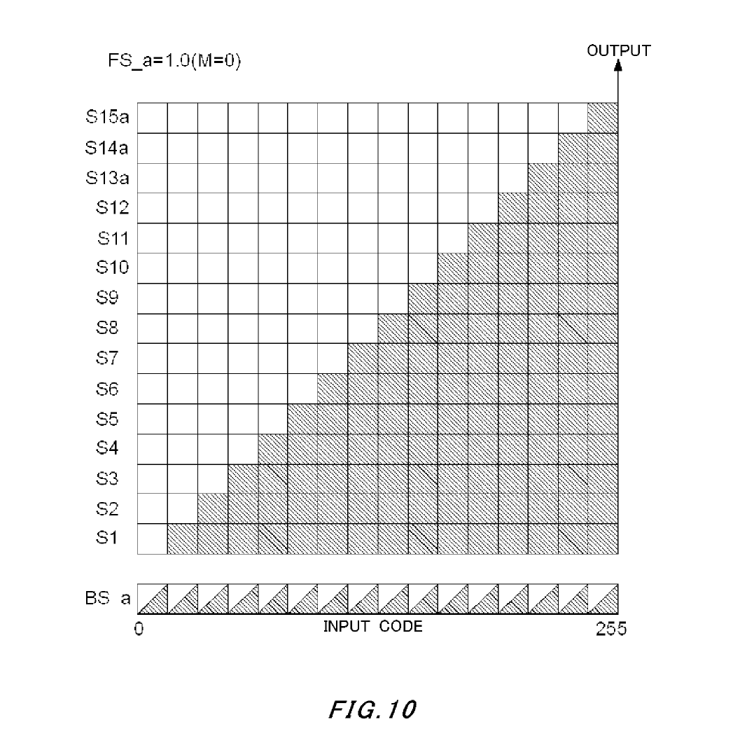

FIG. 11 shows a relationship between an input code of the input digital data Din and an analog level generated according to the first shift data, by using a pattern of the lower-order bit data BSa and the first decoded data (S1 to S15a). In this example, M=1. All other conditions are the same as described in the example of FIG. 10.

In this case, the change pattern of BSa changes with a period of 2⁵=32, with the value of the input code as a variable. The number of bits having a value of 1 in the first decoded data increases by one every time the input code value increases by 32.

As shown in FIG. 11, when M=1, there is a change from a state in which all of the common analog elements 61 are OFF to a state in which approximately half of the common analog elements 61 are ON, according to the increase in the input code. As shown in FIG. 11, the variable width (full scale) of the analog level generated according to the first shift data when M=1 is FS_a=0.5.

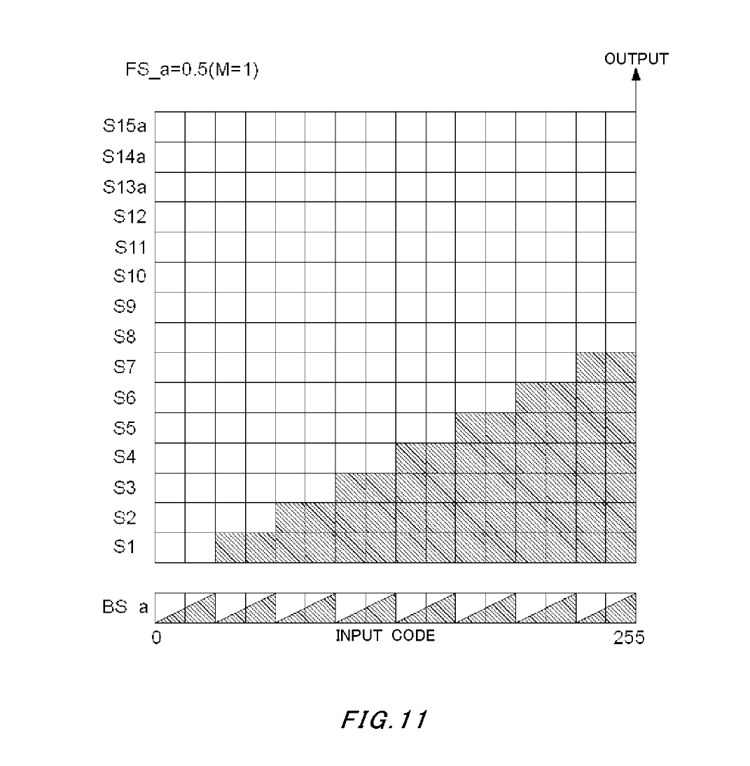

FIG. 12 shows a relationship between an input code of the input digital data Din and an analog level generated according to the first shift data, by using a pattern of the lower-order bit data BSa and the first decoded data (S1 to S15a). In this example, M=2. All other conditions are the same as described in the example of FIG. 10.

In this case, the change pattern of BSa changes with a period of 2⁶=64, with the value of the input code as a variable. The number of bits having a value of 1 in the first decoded data increases by one every time the input code value increases by 64.

As shown in FIG. 12, when M=2, there is a change from a state in which all of the common analog elements 61 are OFF to a state in which approximately one quarter of the common analog elements 61 are ON, according to the increase in the input code. As shown in FIG. 12, the variable width (full scale) of the analog level generated according to the first shift data when M=2 is FS_a=0.25.

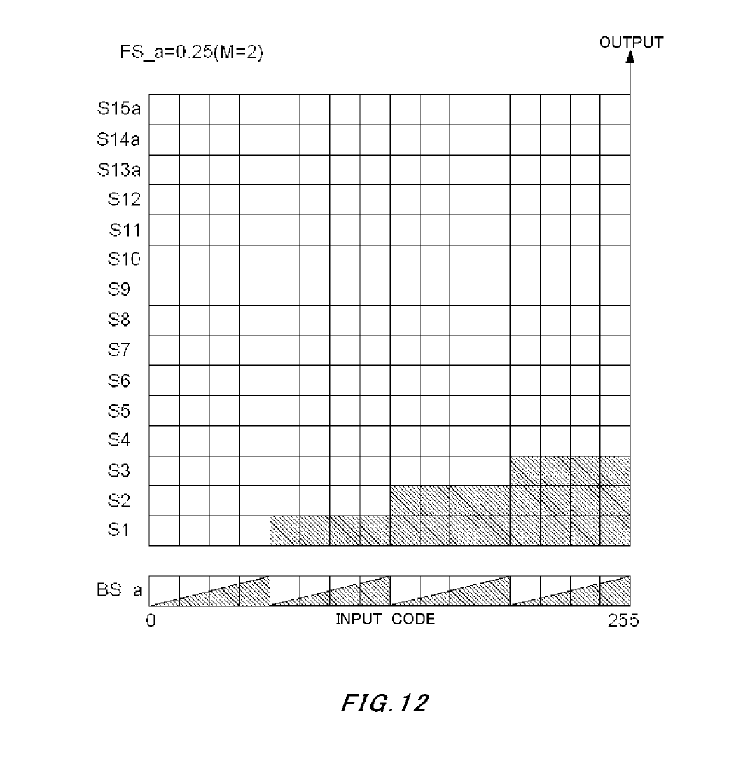

FIG. 13 shows a relationship between an input code of the input digital data Din and an analog level generated according to the second shift data, by using a pattern of the lower-order bit data BSb and the second decoded data (S13b to S15b). In this example, N=2. All other conditions are the same as described in the example of FIG. 10.

In the same manner as the lower-order bit data BSa, the lower-order bit data BSb changes with a period of 2^{(L-k+N)}, with the value of the input code as a variable. Accordingly, the lower-order bit data BSb of the present example changes with a period of 2⁶=64. The number of bits having a value of 1 in the second decoded data increases by one every time the input code value increases by 2^{(L-k+N)}. In the example of FIG. 13, the number of bits having a value of 1 in the second decoded data increases by one every time the input code value increases by 64.

As shown in FIG. 13, when N=2, there is a change from a state in which all of the common analog elements 61 are OFF to a state in which approximately one quarter of the common analog elements 61 are ON, according to the increase in the input code. As shown in FIG. 13, the variable width (full scale) of the analog level generated according to the second shift data when N=2 is FS_b=0.25.

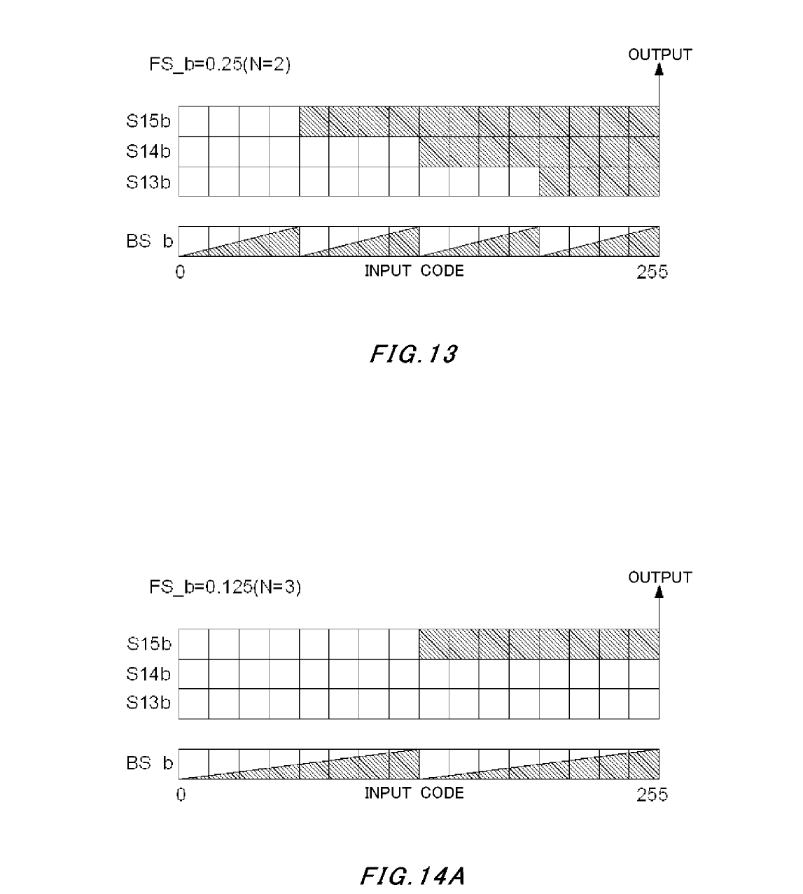

FIG. 14A shows a relationship between an input code of the input digital data Din and an analog level generated according to the second shift data, by using a pattern of the lower-order bit data BSb and the second decoded data (S13b to S15b). In this example, N=3. All other conditions are the same as described in the example of FIG. 10.

The lower-order bit data BSb in this example changes with a period of 2⁷=128. The number of bits having a value of 1 in the second decoded data increases by one every time the input code value increases by 128. As shown in FIG. 14A, the variable width (full scale) of the analog level generated according to the second shift data when N=3 is FS_b=0.125.

FIG. 14B shows a relationship between an input code of the input digital data Din and an analog level generated according to the second shift data, by using a pattern of the lower-order bit data BSb and the second decoded data (S13b to S15b). In this example, N=3. Furthermore, in this example, the inversion control signal has a value of 1, and the sign in the lower-order bit data BSb and the second decoded data is inverted by the higher-order inverting section 74 and the lower-order inverting section 76. All other conditions are the same as described in the example of FIG. 10.

The lower-order bit data BSb in this example changes with a period of 2⁷=128. However, the value of the lower-order bit data BSb decreases uniformly according to the increase of the input code value. The number of bits having a value of 1 in the second decoded data decreases by one every time the input code value increases by 128. As shown in FIG. 14B, the variable width (full scale) of the analog level generated according to the second shift data of this example is FS_b=−0.125.

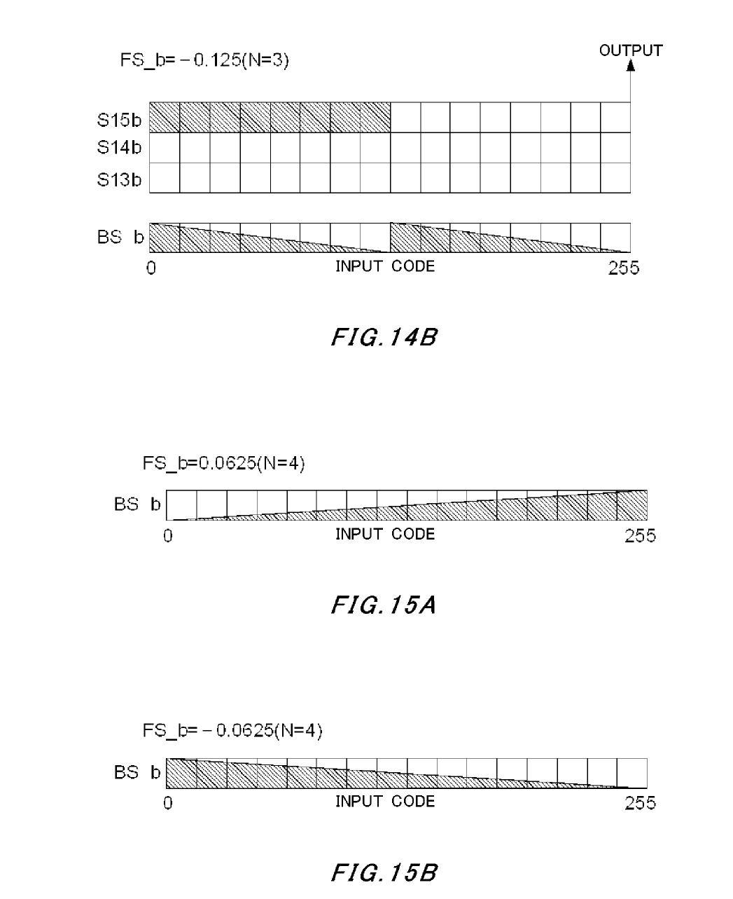

FIG. 15A shows a relationship between an input code of the input digital data Din and an analog level generated according to the second shift data, by using a pattern of the lower-order bit data BSb. In this example, N=4. When N=4 or more, all of the bits in the second decoded data have a value of 0.

The lower-order bit data BSb in this example changes with a period of 2⁸=256. As shown in FIG. 15A, the variable width (full scale) of the analog level generated according to the second shift data in this example is FS_b=0.0625.

FIG. 15B shows a relationship between an input code of the input digital data Din and an analog level generated according to the second shift data, by using a pattern of the lower-order bit data BSb. In this example, N=4. Furthermore, in this example, the inversion control signal has a value of 1, and the sign in the lower-order bit data BSb is inverted by the higher-order inverting section 74 and the lower-order inverting section 76.

The lower-order bit data BSb in this example changes with a period of 2⁸=256. However, the value of the lower-order bit data BSb decreases uniformly according to the increase of the input code value. As shown in FIG. 15B, the variable width (full scale) of the analog level generated according to the second shift data of this example is FS_b=−0.0625.

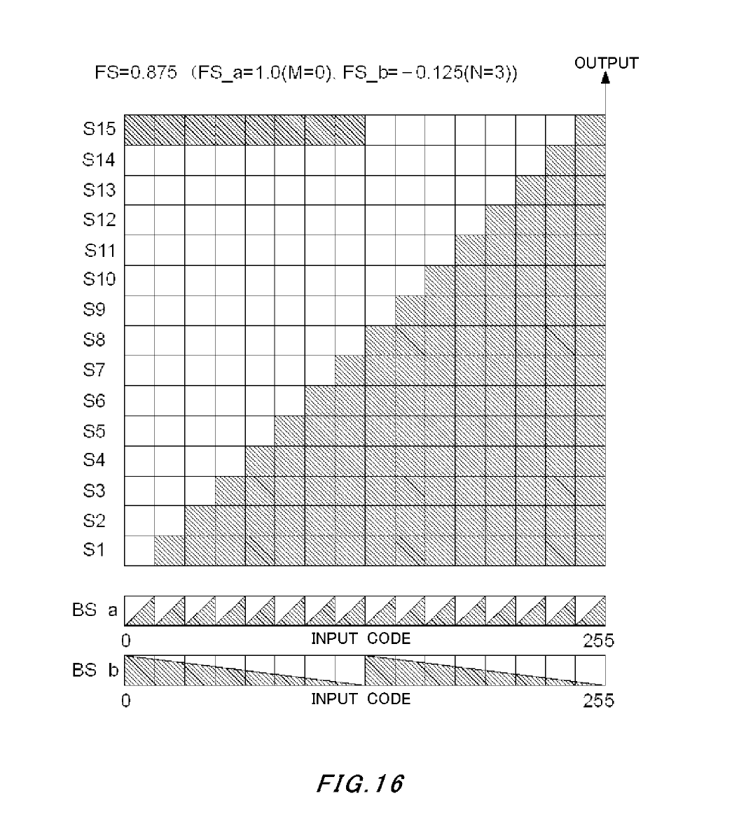

FIG. 16 shows a relationship between an input code of the input digital data Din and a signal level of the output analog signal Sout, by using patterns of the higher-order bit data Sn (S1 to S15), the lower-order bit data BSa, and the lower-order bit data BSb. FIG. 16 shows an example in which M=0 and N=3. Furthermore, in this example, the inversion control signal has a value of 1, and so the output analog signal is generated by subtracting the analog level corresponding to the second shift data from the analog level corresponding to the first shift data.

In this case, the pattern of the higher-order bit data is the logical OR of the pattern of the first decoded data shown in FIG. 10 and the pattern of the second decoded data shown in FIG. 14B. As shown in FIG. 16, when the inversion control signal has a value of 1, the control section 36 further includes a third control state for controlling prescribed common analog elements 61 using both the higher-order bits of the first shift data and the higher-order bits of the second shift data. The control section 36 selects the third control state for the common analog elements 61 on a condition that the higher-order inverting section 74 and the lower-order inverting section 76 invert the sign of the data. A common analog element 61 in the third control state switches between being controlled by the higher-order bits of the first shift data (or first decoded data) and the higher-order bits of the second shift data (or second decoded data), according to the input code, in addition to the bit shift amounts M and N. This control can be realized using the same configuration as shown in FIGS. 4 to 6B, for example.

The patterns for the respective sets of lower-order bit data BS may be the same as the patterns for the lower-order bit data BS shown in FIGS. 10 and 14B. With this embodiment, the common analog element 61 can be used more efficiently. The full scale of the DA converting section 30 in this example is FS=0.875.

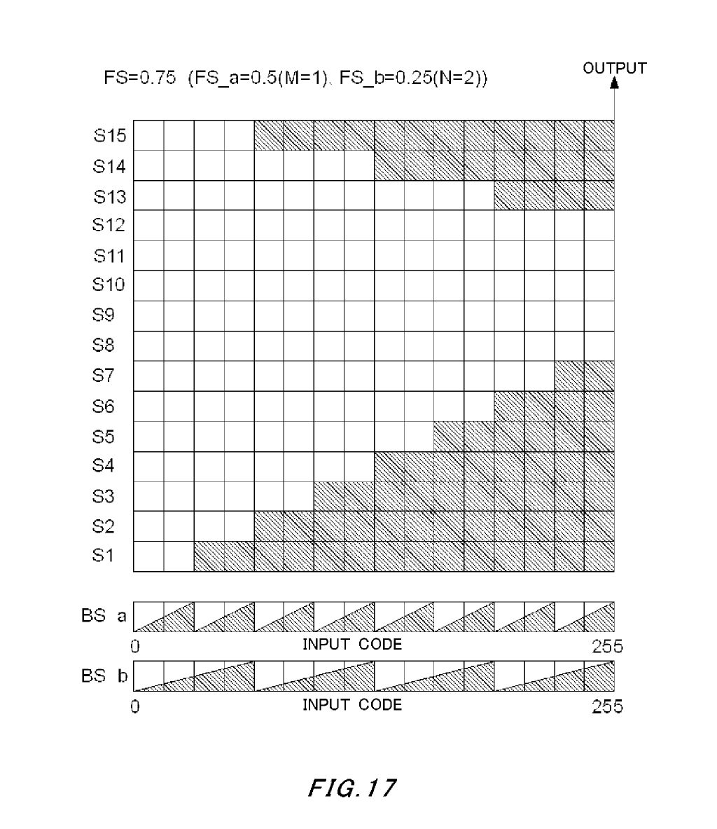

FIG. 17 shows a relationship between an input code of the input digital data Din and a signal level of the output analog signal Sout, by using patterns of the higher-order bit data Sn (S1 to S15), the lower-order bit data BSa, and the lower-order bit data BSb. FIG. 17 shows an example in which M=1 and N=2. Furthermore, in this example, the inversion control signal has a value of 0, and so the output analog signal is generated by adding the analog level corresponding to the second shift data to the analog level corresponding to the first shift data.

In this case, the pattern of the higher-order bit data Sn is the logical OR of the pattern of the first decoded data shown in FIG. 11 and the pattern of the second decoded data shown in FIG. 13. The patterns for the respective sets of lower-order bit data BS may be the same as the patterns for the lower-order bit data BS shown in FIGS. 11 and 13. The full scale of the DA converting section 30 in this example is FS=0.75.

The combinations of bit shift amounts M and N are not limited to the examples shown in FIGS. 16 and 17. A variety of other combinations can be used, including the examples of FIGS. 10 to 13 where M=0 to 2 and the examples of FIGS. 13 to 15 where N=2 to 5.

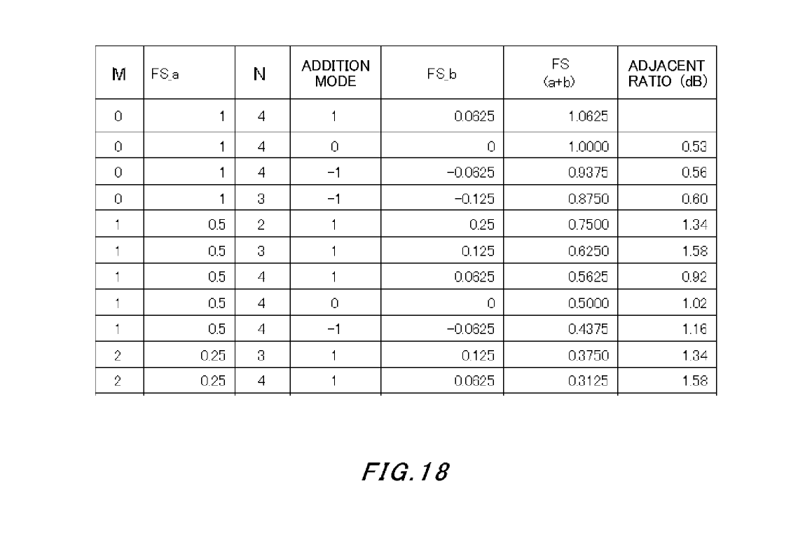

FIG. 18 shows exemplary combinations of bit shift amounts M and N and the full scale FS(a+b) of the DA converting section 30 for these combinations. Rows in FIG. 18 for which the addition mode has a value of 1 indicate examples in which the inversion control signal has a value of 0 (i.e. examples of addition), rows in which the addition mode has a value of −1 indicate examples in which the inversion control signal has a value of 1 (i.e. examples of subtraction), and rows in which the addition mode has a value of 0 indicate examples in which the analog level according to the second shift data is not used. As shown in FIG. 18, by combining the bit shift amounts M and N and the addition mode, a variety of full scales can be realized, and the difference between the FS of adjacent rows can be decreased. Therefore, the noise occurring in the output analog signal can be decreased.

The data setting section 24 may set the bit shift amounts M and N and control the higher-order inverting section 74 and the lower-order inverting section 76 according to an input full scale setting value. The full scale setting value may be data setting the full scale FS of the DA converting section 30 such as shown in FIG. 18, for example.

Generally, in a high-speed DA converter, in order to simplify the bias design of the analog elements, the setting range for the reference voltage is limited. Therefore, in order to control the full scale of the output analog signal, a variable attenuator is inserted downstream from the DA converter. However, providing the variable attenuator increases the circuit size of the analog circuit. Furthermore, when controlling the full scale simply by shifting the input digital data, the step interval becomes approximately 6.02 dB, and the setting range of the reference voltage must be set to a wide range of one octave. In contrast, by performing a DA conversion for a full scale of the analog level corresponding to the first shift data and a different full scale of the analog level corresponding to the second shift data, the DA conversion apparatus 100 can restrict the step interval to be 1.6 dB or less. Therefore, a DA conversion apparatus 100 that generates an output analog signal with little noise can be realized with a small circuit size.

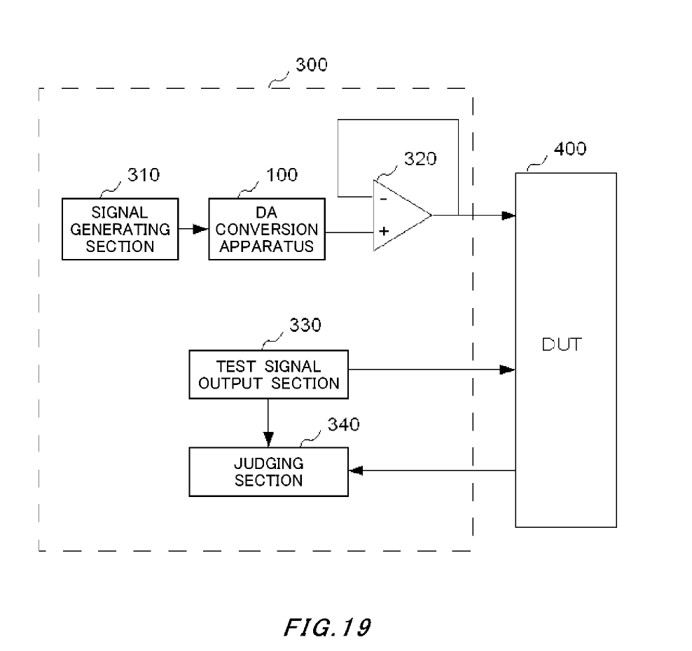

FIG. 19 shows a configuration of a test apparatus 300, along with a device under test 400. The test apparatus 300 tests the device under test 400, which may be an analog circuit, a digital circuit, a memory, a system on chip (SOC), or the like.

The test apparatus 300 includes a signal generating section 310, the DA conversion apparatus 100, a voltage supplying section 320, a test signal output section 330, and a judging section 340. The DA conversion apparatus 100 generates voltage to be applied to the device under test 400. The DA conversion apparatus 100 has the same configuration as the DA conversion apparatus 100 described in the embodiments of FIGS. 1 to 9, and therefore redundant descriptions are omitted.

The signal generating section 310 outputs to the DA conversion apparatus 100 the voltage to be supplied to the device under test 400, as a digital value. The DA conversion apparatus 100 outputs an output analog signal corresponding to input digital data provided thereto. The voltage supplying section 320 supplies the device under test 400 with a test voltage corresponding to the output analog signal generated by the DA conversion apparatus 100. The voltage supplying section 320 may be a power amplifier, for example. The DA conversion apparatus 100 may output an analog waveform having a prescribed period, or may output a constant analog level.

The test signal output section 330 outputs a test signal to the device under test 400. The DA conversion apparatus 100 may be used as a portion of the test signal output section 330. The test signal output section 330 may output to the judging section 340 an expected value that is expected to be output by the device under test 400 in response to the test signal. The judging section 340 receives from the device under test 400 a response signal corresponding to the test signal. The judging section 340 determines pass/fail of the device under test 400 based on the received response signal.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A DA conversion apparatus that converts input digital data into an output analog signal, comprising:
a DA converting section that includes a plurality of analog elements and generates the output analog signal by combining each of a plurality of analog levels output by the analog elements; and
a control section that generates first shift data and second shift data by shifting the input digital data by respective shift amounts of M bits and N bits, and controls the analog elements based on the first shift data and the second shift data, wherein
two or more of the analog elements are common analog elements that are provided in common for the first shift data and second shift data, and
the control section changes a control state for each of the common analog elements according to the bit shift amounts M and N in the control section, between at least two control states including a control state in which the common analog element is controlled according to higher-order bits of the first shift data and a control state in which the common analog element is controlled according higher-order bits of the second shift data.

2. The DA conversion apparatus according to claim 1, wherein
the control section changes the control state for each common analog element according to the bit shift amounts M and N, between the at least two control states further including a control state in which the common analog element is controlled using both the higher-order bits of the first shift data and the higher-order bits of the second shift data.

3. The DA conversion apparatus according to claim 1, wherein
the control section changes the control state for each common analog element according to the bit shift amounts M and N, between the at least two control states further including a control state in which the common analog element is controlled to be disabled.

4. The DA conversion apparatus according to claim 3, wherein
the control section controls, to be disabled, common analog elements that are controlled according to neither the first shift data nor the second shift data.

5. The DA conversion apparatus according to claim 1, wherein
at least two of the analog elements, which are not the common analog elements, are first analog elements that are controlled by lower-order bits of the first shift data, and
at least two of the analog elements, which are neither the common analog elements nor the first analog elements, are second analog elements that are controlled by lower-order bits of the second shift data.

6. The DA conversion apparatus according to claim 5, wherein
change amounts of analog levels received respectively by the first analog elements increase in a binary manner among the first analog elements,
change amounts of analog levels received respectively by the second analog elements increase in a binary manner among the second analog elements, and
change amounts of analog levels received respectively by the common analog elements are the same as each other.

7. The DA conversion apparatus according to claim 6, wherein the control section includes:
a decoder circuit that decodes the higher-order bits of the first shift data and the higher-order bits of the second shift data into respective sets of decoded data; and
a logical OR section that generates higher-order bit data for controlling the common analog elements that has a number of digits equal to the number of common analog elements, based on a logical OR of the two sets of decoded data resulting from the decoding by the decoder circuit.

8. The DA conversion apparatus according to claim 7, wherein the control section further includes:
a higher-order inverting section that controls whether a sign of the decoded data resulting from the decoding of the higher-order bits of the second shift data is inverted; and
a lower-order inverting section that controls whether a sign of data of the lower-order bits of the second shift data is inverted.

9. The DA conversion apparatus according to claim 8, wherein
the control section further includes a data setting section that sets the bit shift amounts M and N and controls the higher-order inverting section and the lower-order inverting section, according to a full scale setting value input thereto.

10. The DA conversion apparatus according to claim 1, wherein the DA converting section includes 2^{k}-1 common analog elements, where k is an integer, and
the control section generates the first shift data and the second shift data such that when one of the bit shift amounts M and N is 0, the other bit shift amount is greater than or equal to k.

11. The DA conversion apparatus according to claim 8, wherein
the control section is capable of selecting, for each common analog element, a control state in which the common analog element is controlled by both the higher-order bits of the first shift data and the higher-order bits of the second shift data, on a condition that the higher-order inverting section and the lower-order inverting section invert the sign of the data.

12. A test apparatus that tests a device under test, comprising:
the DA conversion apparatus according to claim 1; and
a voltage supplying section that applies to the device under test a test voltage corresponding to an output analog signal output by the DA conversion apparatus.
